(19) United States
(12) Patent Application Publication
(10) Pub. No.: US 2014/0033528 A1
(43) Pub. Date: Feb. 6, 2014

(54) METHOD OF FAST DEVICE ATTACHMENT

(71) Applicant: LI-YU LIN, New Taipei City (TW)

(72) Inventor: LI-YU LIN, New Taipei City (TW)

(21) Appl. No.: 13/568,118

(22) Filed: Aug. 6, 2012

(51) Int. Cl. H05K 3/10

(52) U.S. Cl. 29/846

(57) ABSTRACT

A method to fast print an electrical circuit on a surface of a ceramic heat-dissipation substrate and simultaneously adhere electronic devices, comprising the following steps: a. Using the method of printing, spraying, transfer-printing, or the similar to form a solderable metal adhesive layer on a surface of a heat-dissipation substrate; b. Forming a necessary electrical circuit on the surface of the heat-dissipation substrate via burning and solidifying the solderable metal adhesive layer; c. Spreading solder paste and positioning related Surface Mount Device (SMD) on the electrical circuit; d. Placing the heat-dissipation substrate into a furnace having liquidized metal inside, and partially diving the heat-dissipation substrate into the liquidized metal to heat and melt the solder paste via the thermal energy conducted from the liquidized metal, therefore the SMD is adhered on the electrical circuit; and e. Cooling down the heat-dissipation substrate via placing it into a plurality of cooling-chambers.

### TECHNICAL FIELD OF THE INVENTION

The present invention relates to a fast adhesion method to adhere electronic devices on a ceramic heat-dissipation substrate, and more particularly, to a method for adhering the electronic devices easy to produce heat during operation, such as LED chip or the similar on a ceramic heat-dissipation substrate.

### DESCRIPTION OF THE PRIOR ART

Presently, the reflow furnace for the production process of the ordinary Printed Circuit Board (PCB) normally adopts the heating system having multiple thermal sections. After all of the pasted-sheet elements having been mounted, they will be sent into the reflow furnace which is a heating system having multiple thermal sections. The temperature difference will induce the change of the state of the solder paste because the solder paste is constituted by multiple materials. The solder paste is changed into the liquidized state in the high temperature section, such that the pasted-sheet elements are easy to solder with the electrical circuit board. When entering into the cooler section, the solder paste is changed into the solid state, such that the element leads and the electrical circuit board will be firmly connected by the solid solder paste. The types of the reflow furnace may be roughly divided as thermal-wind reflow furnace, nitrogen reflow furnace, laser reflow furnace, and infrared reflow furnace, etc. . . .

The infrared reflow furnace, for example, the temperature of its radiation body is about 600˜2200° C. but normally the melting point of the solder paste is around 200˜250° C., so that most of the reflow furnaces adopt the manner of radiation and convection to raise up the temperature to prevent from touching with the electrical circuit board and the pasted-sheet elements. Reflow furnace is convenient to solder the pasted-sheet elements on the electrical circuit board, but the electrical circuit substrate needs to have the quick thermal dissipation ability if it is a thermal conductor itself. Therefore, it will make the reflow furnace can not adopt the manner of radiation and convection to let the temperature of the solder paste rise and fall rapidly, i.e., it will need a long heating time up to the melting temperature of the solder paste and be unable to use the cool air to rapidly decrease the temperature after the solder paste is melted.

The ordinary pasted-sheet elements can't sustain the high-temperature environment for a long time as shown in FIG. 7.

FIG. 7 represents the reflow requirements for an ordinary Light-Emitting-Diode (LED) pasted-sheet element, it explains that the preheat temperature is suggested as 180˜200° C.; the longest time duration is 120 seconds; and the longest time duration can't exceed 60 seconds when the temperature is over 220° C. If the aforementioned requirements are not satisfied, the element function will be damaged or even burned out.

### SUMMARY OF THE INVENTION

The major objective of the present invention is to provide a method to fast adhere the electronic devices on the surface of the heat-dissipation substrate.

Another objective of the present invention is to provide a method of fast device attachment which will not damage the electronic devices in the adhering process.

To achieve the objective mentioned above, the method of fast device attachment according to the present invention comprises the following steps:

a. Using the method of printing, spraying, transfer-printing, or the similar to form a solderable metal adhesive layer on a surface of a heat-dissipation substrate;

b. Forming a necessary electrical circuit on the surface of the heat-dissipation substrate via burning and solidifying the solderable metal adhesive layer;

c. Spreading a solder paste and positioning related Surface Mount Devices (SMDs) on the necessary electrical circuit;

d. Placing the heat-dissipation substrate having the SMDs on its surface into a furnace having a liquidized metal inside, and partially diving the heat-dissipation substrate into the liquidized metal to heat and melt the solder paste via the thermal energy conducted from the liquidized metal, therefore the related SMDs are adhered on the electrical circuit; and

e. Cooling down the heat-dissipation substrate having the related SMDs on its surface via placing it into a plurality of cooling-chambers.

The method of fast device attachment as mentioned above, wherein the heat-dissipation substrate of step a. may be an electrically isolated ceramic heat-dissipation substrate or a metallic substrate spread with isolation film

The method of fast device attachment as mentioned above, wherein the ceramic substrate may be anyone of the thermal-conductive ceramic, porous ceramic, or graphite ceramic.

The method of fast device attachment as mentioned above, wherein the solderable metal adhesive layer of step a. may be solderable copper paste (adhesive) or silver paste (adhesive).

The method of fast device attachment as mentioned above, wherein the printing type of step a. may be screen printing or stencil minting.

The method of fast device attachment as mentioned above, wherein the related SMDs of step c. may be anyone of the LED chips, power ICs, ICs, or the combination thereof.

The method of fast device attachment as mentioned above, wherein the plurality of cooling-chambers are the high-temperature, high-middle-temperature, middle-temperature, and low-temperature cooling-chambers which cooling temperature are successively decreased.

The advantages of the present invention comparing to the conventional techniques are:

1. Forming a necessary electrical circuit directly on the surface of the heat-dissipation substrate is without the need to connect another electrical circuit board, this can effectively prevent the electronic devices on it from being damaged by the high temperature;

2. Utilizing the advantage of the ceramic heat-dissipation substrate can rapidly conduct and dissipate the heat, and partially diving the heat-dissipation substrate into the liquidized metal can further effectively conduct the heat energy of the furnace to the surface of the ceramic heat-dissipation substrate, therefore the electronic devices can be adhered on the electrical circuit of the surface of the ceramic heat-dissipation substrate; and

3. The multiple stages of cooling operation after the heat-dissipation substrate having been adhered with the electronic devices can prevent the heat-dissipation substrate from damage owing to the rapid cooling.

### BRIEF DESCRIPTION OF THE DRAWINGS

FIG. 1 is a block diagram of the production flowchart according to the present invention.

FIG. 2 is a top-view schematic diagram of the ceramic heat-dissipation substrate of the preferred embodiment according to the present invention to show the forming electrical circuit on the top surface.

FIG. 3 is a top-view schematic diagram of the ceramic heat-dissipation substrate of the preferred embodiment according to the present invention to show the top electrical circuit adhering with the light emitting element.

FIG. 4 is a production flowchart of the preferred embodiment according to the present invention to show the multi-stage cooling down after the adhering of the electronic devices on the ceramic heat-dissipation substrate is completed.

FIG. 5 is a perspective view of the outlook schematic diagram of the preferred embodiment according to the present invention.

FIG. 6 is an exploded view of the element schematic diagram of the preferred embodiment according to the present invention.

FIG. 7 shows the reflow requirements for an ordinary Light-Emitting-Diode (LED) pasted-sheet element.

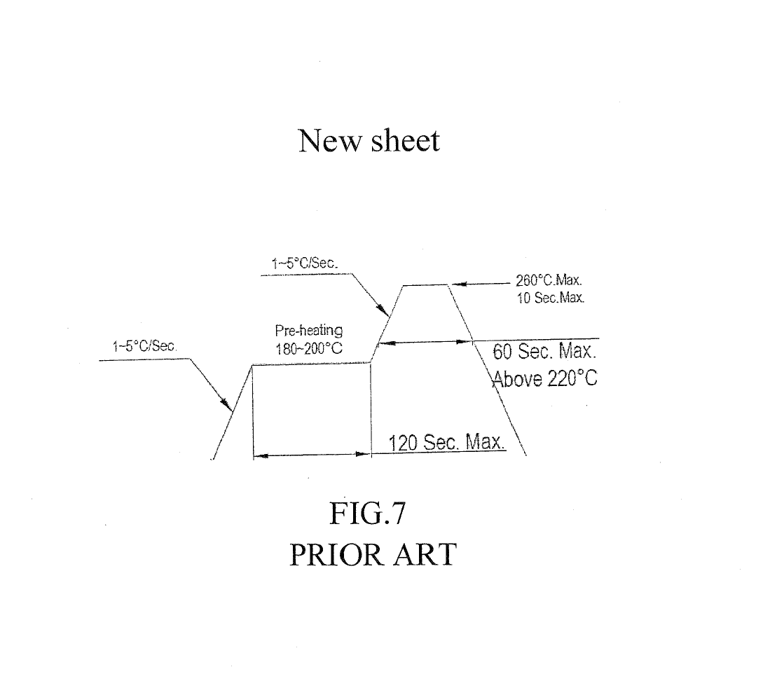

### DETAILED DESCRIPTION OF THE PREFERRED EMBODIMENTS

The following descriptions are exemplary embodiments only, and are not intended to limit the scope, applicability or configuration of the invention in any way. Rather, the following detailed description provides a convenient illustration for implementing exemplary embodiments of the invention. Various changes to the described embodiments may be made in the function and arrangement of the elements described without departing from the scope of the invention as set forth in the appended claims.

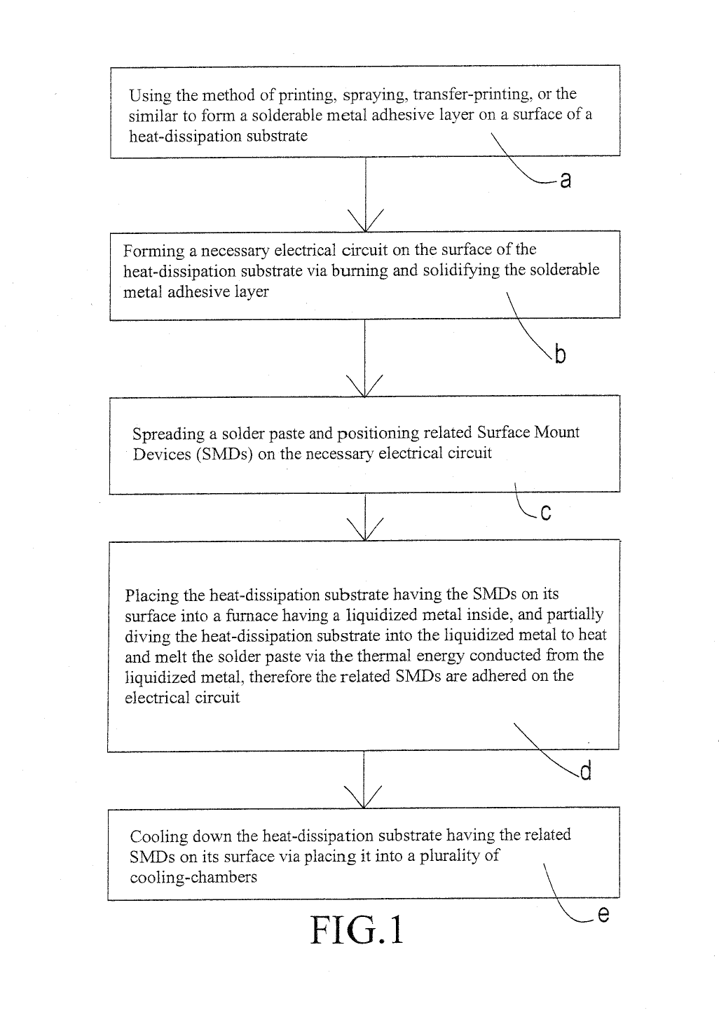

Please refer to FIG. 1; the method of fast device attachment according to the present invention comprises the following steps:

a. Using the method of printing, spraying, transfer-printing, or the similar to form a solderable metal adhesive layer on a surface of a heat-dissipation substrate;

b. Forming a necessary electrical circuit on the surface of the heat-dissipation substrate via burning and solidifying the solderable metal adhesive layer;

c. Spreading a solder paste and positioning related SMDs on the necessary electrical circuit;

d. Placing the heat-dissipation substrate having the related SMDs on its surface into a furnace having a liquidized metal inside, and partially diving the heat-dissipation substrate into the liquidized metal to heat and melt the solder paste via the thermal energy conducted from the liquidized metal, therefore the related SMDs are adhered on the electrical circuit; and

e. Cooling down the heat-dissipation substrate having the related SMDs on its surface via placing it into a plurality of cooling-chambers.

The heat-dissipation substrate of step a. may be an electrically isolated ceramic heat-dissipation substrate or a metallic substrate spread with isolation film The ceramic substrate may be anyone of the thermal-conductive ceramic, porous ceramic, or graphite ceramic. The solderable metal adhesive layer may be solderable copper paste (adhesive) or silver paste (adhesive). The printing type may be anyone of the screen printing, stencil printing, spraying, or transfer-printing.

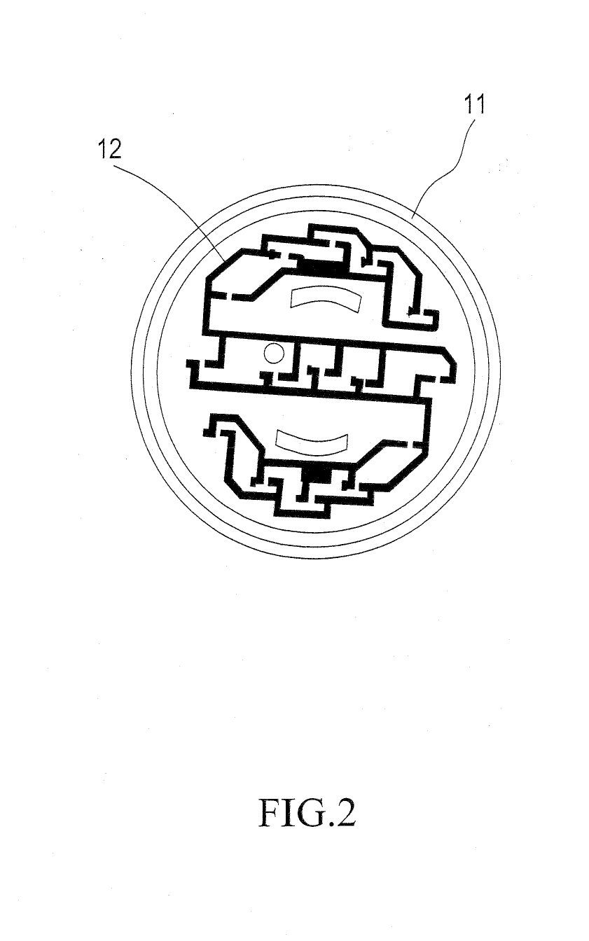

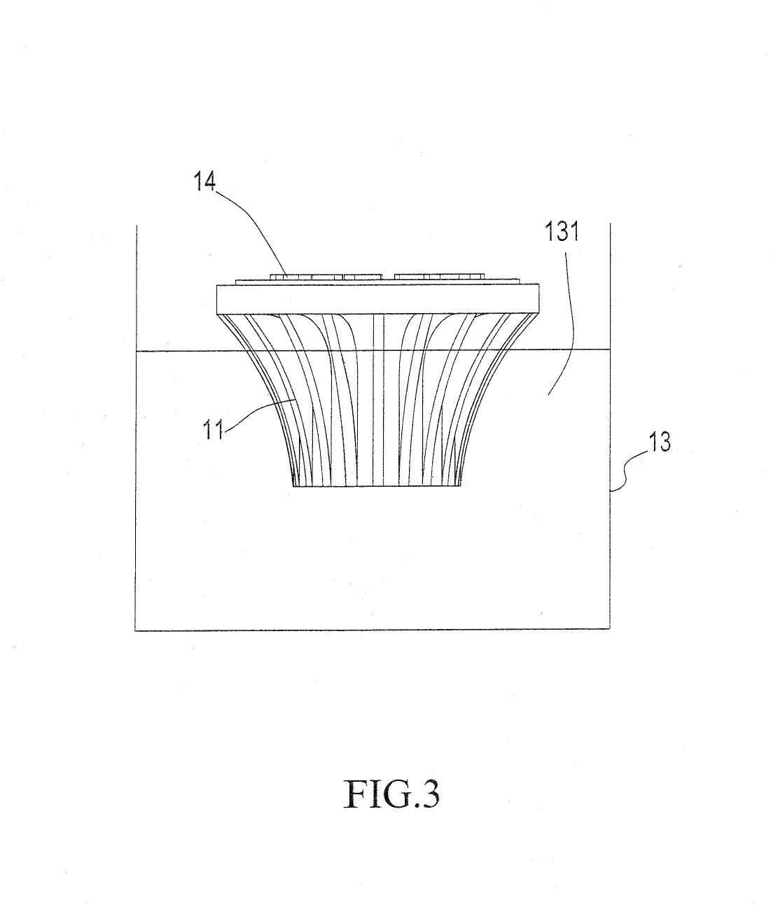

Please refer to FIG. 2; the solderable metal adhesive layer is formed on the top surface of the heat-dissipation substrate 11 by using the method of printing, spraying, transfer-printing. Then, the electrical circuit 12 is formed via burning and solidifying at 100˜300° C. and then solder paste is spread and the SMD is positioned on the electrical circuit 12. The SMD of this preferred embodiment is to use LED as an example to explain. The proceeding step is to place the heat-dissipation substrate 11 having the LED 14 on its top surface into a furnace 13 having a liquidized metal 131 inside, and partially diving the heat-dissipation substrate 11 into the liquidized metal 131. Then, the thermal energy of the liquidized metal 131 is conducted to the electrical circuit 12 on the top surface of the heat-dissipation substrate 11 via the heat-dissipation substrate 11. At the meantime, the LED 14 is adhered on the electrical circuit 12 via the solder paste as shown in FIG. 3.

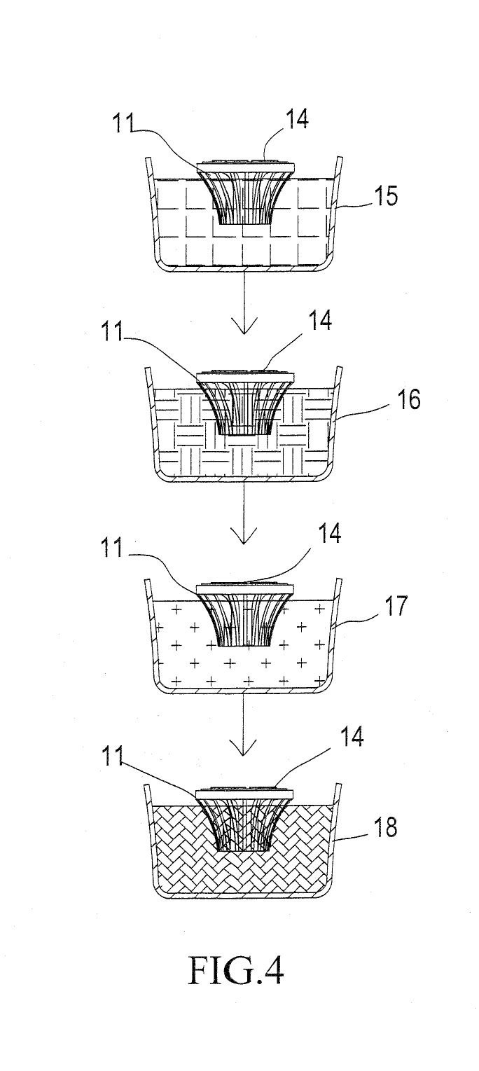

After the heat-dissipation substrate 11 has accomplished adhering with the LED 14, it is moved out from the furnace 13 and moved into a high-temperature cooling-chamber 15 to be cooled down for a period time. Then, it is successively moved into the high-middle-temperature, middle-temperature, and low-temperature cooling-chambers 16, 17, and 18 to be cooled down for a period of time each as shown in FIG. 4. This gradient cooling way for the heat-dissipation substrate 11 can prevent the heat-dissipation substrate 11 from crisping or damage owing to the rapid cooling.

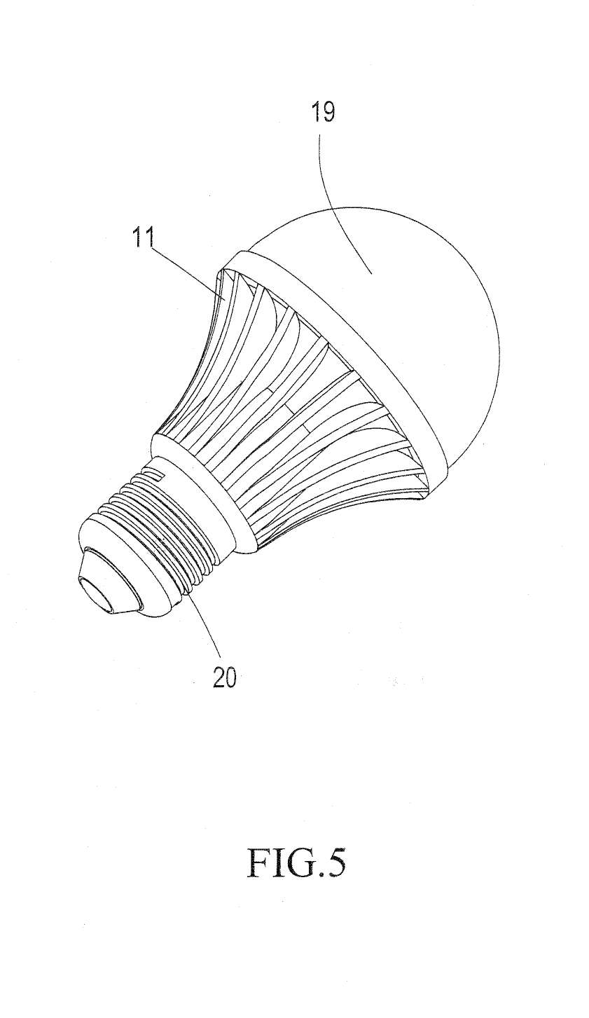

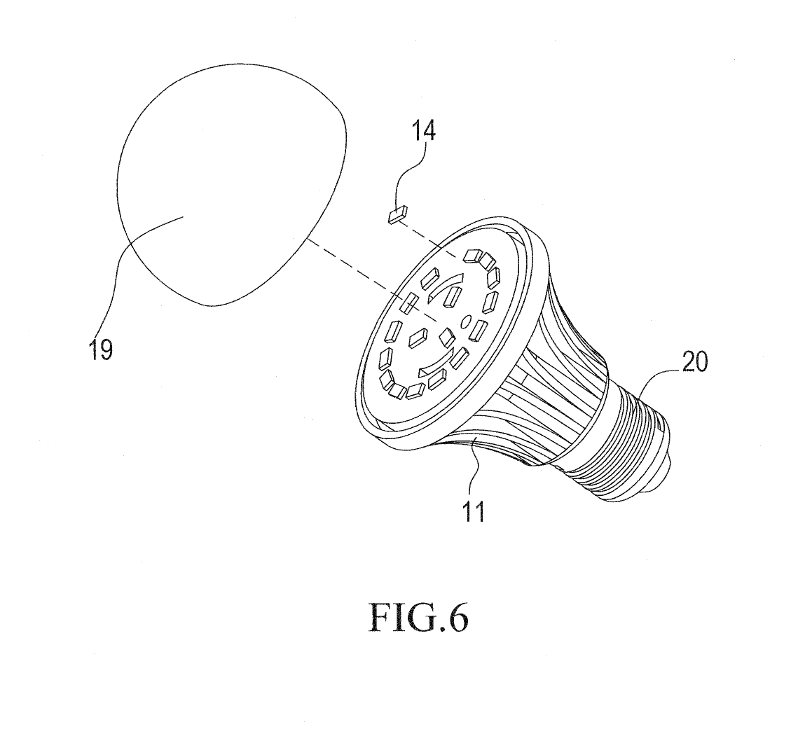

Please simultaneously refer to FIG. 5 and FIG. 6; the electrical circuit 12 on the top surface of the heat-dissipation substrate 11 having been slowly cooled has another two leads set inside the heat-dissipation substrate 11. The bottom of the heat-dissipation substrate 11 is then combined with the connector of the lamp holder 20, wherein the two leads are electrically connected with the connector of the lamp holder 20. And, the electrical circuit 12 on the top surface of the heat-dissipation substrate 11 also combines with a transparent cap 19. Through the aforementioned configuration, the thermal energy generated by the LED 14 is dissipated via the heat-dissipation substrate 11 when the LED 14 emits light through accepting the electrical power.

I claim:

1. A method of fast device attachment, comprising the following steps:
a. Using the method of printing, spraying, transfer-printing, or the similar to form a solderable metal adhesive layer on a surface of a heat-dissipation substrate;
b. Forming a necessary electrical circuit on the surface of the heat-dissipation substrate via burning and solidifying the solderable metal adhesive layer;
c. Spreading a solder paste and positioning related Surface Mount Devices (SMDs) on the necessary electrical circuit;
d. Placing the heat-dissipation substrate having the SMDs on its surface into a furnace having a liquidized metal inside, and partially diving the heat-dissipation substrate into the liquidized metal to heat and melt the solder paste via the thermal energy conducted from the liquidized metal, therefore the related SMDs are adhered on the electrical circuit; and
e. Cooling down the heat-dissipation substrate having the related SMDs on its surface via placing it into a plurality of cooling-chambers.

2. The method of fast device attachment according to claim 1, wherein the heat-dissipation substrate of step a. is an electrically isolated ceramic heat-dissipation substrate or a metallic substrate spread with isolation film.

3. The method of fast device attachment according to claim 1, wherein the ceramic substrate is selected from anyone of the thermal-conductive ceramic, porous ceramic, or graphite ceramic.

4. The method of fast device attachment according to claim 1, wherein the solderable metal adhesive layer of step a. is solderable copper paste (adhesive) or silver paste (adhesive).

5. The method of fast device attachment according to claim 1, wherein the printing type of step a. may be screen printing or stencil printing.

6. The method of fast device attachment according to claim 1, wherein the related SMDs of step c. is selected from anyone of the LED chips, power ICs, ICs, or the combination thereof.

7. The method of fast device attachment according to claim 1, wherein the plurality of cooling-chambers of step e. are the high-temperature, high-middle-temperature, middle-temperature, and low-temperature cooling-chambers which cooling temperature are successively decreased.
